(19) United States
(12) Patent Application Publication
(10) Pub. No.: US 2026/0268971 A1
(43) Pub. Date: Sep. 10, 2026

(54) MEMORY AND CONTROL METHOD THEREOF

(71) Applicant: Xiamen Industrial Technology Research Institute Co.,Ltd., Xiamen (CN)

(72) Inventors: Tianlong Pan, Xiamen (CN); Meidong Liu, Xiamen (CN); Jiayu Yin, Xiamen (CN); Zhexin Zheng, Zhangzhou (CN); Lixia Bai, Xiamen (CN); Yuhuang Chen, Xiamen (CN)

(21) Appl. No.: 19/662,561

(22) Filed: Apr. 29, 2026

(30) Foreign Application Priority Data
Dec. 2, 2025 (CN) 202511798940.4

(51) Int. Cl. G11C 13/00

(52) U.S. Cl. CPC G11C 13/004

(57) ABSTRACT

Provided are a memory and a control method thereof. The memory includes a reading circuit and a storage array, the signal includes a storage cell and at least one row of reference cells parallel to the storage cell, the reference cell includes first reference switch transistors with the same number of storage switches in the storage cell; the reading circuit includes a sense amplifier and a reference array cell. A data input terminal of the sense amplifier is electrically connected to a bit line of the storage cell through a data switch transistor, and a reference input terminal is electrically connected to an output terminal of the reference array cell. An input terminal of the reference array cell is electrically connected to a reference line that is connected to all reference cells through a second reference switch transistor.

### CROSS-REFERENCE TO RELATED APPLICATIONS

This application claims priority to Chinese Patent Application No. 202511798940.4, filed on Dec. 2, 2025, which is hereby incorporated by reference in its entirety.

### TECHNICAL FIELD

The present disclosure relates to the field of semiconductor technologies, and in particular, to a memory and a control method thereof.

### BACKGROUND

In memory, taking Resistive Random Access Memory (RRAM) as an example, as shown in FIG. 3, a bit line (BL) of a storage array is connected to a data input terminal of a sense amplifier (SA) of a reading circuit, and a reference input terminal of the sense amplifier is provided by a reference array cell. A data output of the storage array is performed by comparing a data signal with the reference signal through the sense amplifier.

In RRAM, as the length of the BL increases, the parasitic effects on the BL also increase, thereby affecting the data signal at the data input terminal of the sense amplifier. At the same time, when reading RRAM site selection, there may be slight VDS leakage on the transistors of unselected storage cells, which can also affect the data signal of the sense amplifier. The reference signal of the sense amplifier is fixedly generated by the reference array cell, which may result in errors with the data signal affected by parasitic and leakage effects, leading to errors in the memory when reading data.

### SUMMARY

In order to solve the above-mentioned problems of the prior art, the present disclosure provides a memory and its control method to improve the accuracy of reading.

In order to achieve the above objectives, the technical solution adopted by the present disclosure is as flows.

In a first aspect, the present disclosure provides a memory, where the memory includes a reading circuit and a storage array, the storage array includes a storage cell and at least one row of reference cells parallel to the storage cell, the reference cells include first reference switch transistors with the same number of storage switch transistors in the storage cell;

the reading circuit includes a sense amplifier and a reference array cell; a data input terminal of the sense amplifier is electrically connected to a bit line of the storage cell through a data switch transistor, and a reference input terminal is electrically connected to an output terminal of the reference array cell; an input terminal of the reference array cell is electrically connected to a reference line that is connected to all reference cells through a second reference switch transistor.

The beneficial effect of the present disclosure is to add at least one row of reference cells in the storage array, which includes the same number of first reference switch transistors as the storage switch transistors in the storage cells, and to electrically connect the reference lines of all reference cells connected to the input terminal of the reference array cells. Therefore, when reading data from the storage cell, the control of the second reference switch is used to conduct the signal reading on the reference cell as a reference path, so that a data path and the reference path are completely symmetrical to offset parasitic and leakage effects, thereby reducing errors at two ends of the sense amplifier data and improving the accuracy of reading.

In some embodiments of the present disclosure, the storage array is an RRAM array.

In some embodiments of the present disclosure, the reference cell includes only two reference switch transistors that are connected.

In some embodiments of the present disclosure, the reading circuit further includes a reference compensation cell, and an output terminal of the reference compensation cell is electrically connected to the input terminal of the reference array cell through a compensation switch transistor.

In some embodiments of the present disclosure, the compensation switch is the same as the second reference switch and has the same control signal.

In a second aspect, the present disclosure provides a control method applied to the memory as described in the first aspect, the control method including the steps of:
conducting a data switch transistor and inputting data signal read from a selected storage cell to a sense amplifier;
conducting a second reference switch transistor, inputting a signal read from a reference line to a reference array cell, and generating a reference signal from the reference array cell to output to the sense amplifier;
obtaining data reading results based on the data signal and reference signal by the sense amplifier.

In some embodiments of the present disclosure, the storage array is an RRAM array.

In some embodiments of the present disclosure, the reference cell includes only two first reference switch transistors that are connected.

In some embodiments of the present disclosure, it also includes the following steps:

outputting a reference compensation signal, by the reference compensation cell, to the reference array cell by conducting the compensation switch transistor.

In some embodiments of the present disclosure, the compensation switch is the same as the second reference switch and has the same control signal.

Where the technical effect corresponds to the control method provided in the second aspect refers to the relevant description of the memory provided in the first aspect.

### BRIEF DESCRIPTION OF DRAWINGS

FIG. 1 is a schematic structural diagram of memory according to an embodiment of the present disclosure.

FIG. 2 is a schematic structural diagram of RRAM involved in the prior art.

FIG. 3 is a flowchart of a control method according to an embodiment of the present disclosure.

### DESCRIPTION OF EMBODIMENTS

In order to better understand the above technical solution, exemplary embodiments of the present disclosure will be described in more detail below with reference to the accompanying drawings. Although exemplary embodiments of the present disclosure are shown in the accompanying drawings, it should be understood that the present disclosure may be implemented in various forms and should not be limited by the embodiments described herein. On the contrary, these embodiments are provided to enable a clearer and more thorough understanding of the present disclosure, and to fully convey the scope of the present disclosure to those skilled in the art.

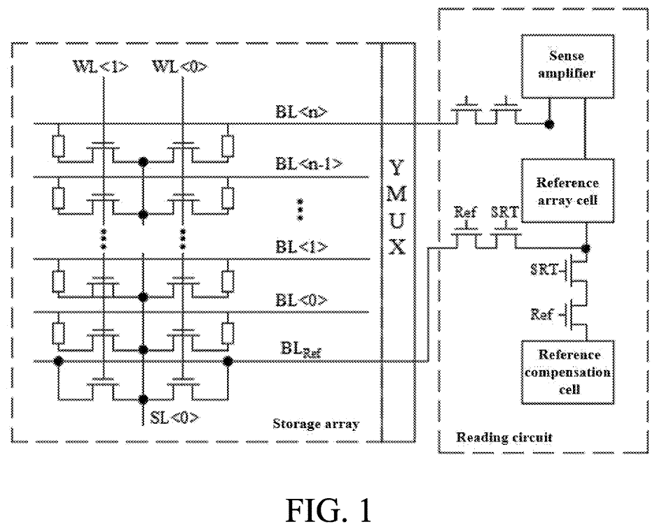

A first aspect of the present disclosure provides a memory, as shown in FIG. 1, including a reading circuit and a storage array. The storage array includes a storage cell and at least one row of reference cells parallel to the storage cell. The reference cells include first reference switch transistors with the same number of storage switch transistors in the storage cell. Where the reading circuit includes a sense amplifier and a reference array cell. A data input terminal of the sense amplifier is electrically connected to a bit line of the storage cell through a data switch transistor, and the reference input terminal is electrically connected to an output terminal of the reference array cell. An input terminal of the reference array cell is electrically connected to a reference line that is connected to all reference cells through a second reference switch transistor.

As shown in FIG. 1, in an embodiment, the storage array is an RRAM array, and the storage cells in the RRAM array adopt a 2T2R structure, including two storage switch transistors and two resistance switch resistors. In this example, the storage switch transistors are MOS transistors, where one end of a first resistance switch resistor is connected to BL, and the other end is connected to a drain electrode of the first storage switch transistor. Source electrodes of the two storage switch transistors are connected to a source line (Source Line, SL), and gate electrodes of the two storage switch transistors are connected to their respective word lines (Word Line, WL). A drain electrode of a second storage switch transistor is connected to one end of the second resistance switch resistor, and the other end of the second resistance switch is also connected to the same BL. Where BL and WL are wired horizontally in parallel, and the SL is wired vertically. In this example, a reference cell is further provided on the storage array, and the reference cell only includes two first reference switch transistors that are connected. Source electrodes of the two first reference switch transistors are connected to a reference line BLRef, source electrodes are commonly connected to SL, and the gate electrodes are respectively connected to WL. BLRef is electrically connected to the input terminal of the reference array cell through the second reference switch transistor.

In this example, the reference cell is only set to one row, and a layout of the reference cell in that row is exactly the same as that of the storage cell to ensure consistency between the subsequent data path and the reference path.

As shown in FIG. 1, in this example, when reading the storage cells in a n^{th} row and a m^{th} column of the storage array, turning on a data switch on the storage array to input a data signal output by a Y multiplexer (YMUX) in the storage array to a data input terminal of the sense amplifier. At this point, selecting the reference line BLRef, turning on the second reference switch transistor on the reference array cell, so that read signal on the reference line of the reference cell is input to the input terminal of the reference array cell, and a reference signal generated by the reference array cell is output to a reference input terminal of the sense amplifier. At this point, the data path and reference path are completely symmetrical and also have unselected VDS leakage accumulation of the entire path, which is equivalent to the synchronous loss of the data signal and reference signal of the sense amplifier, thereby offsetting the parasitic and leakage effects.

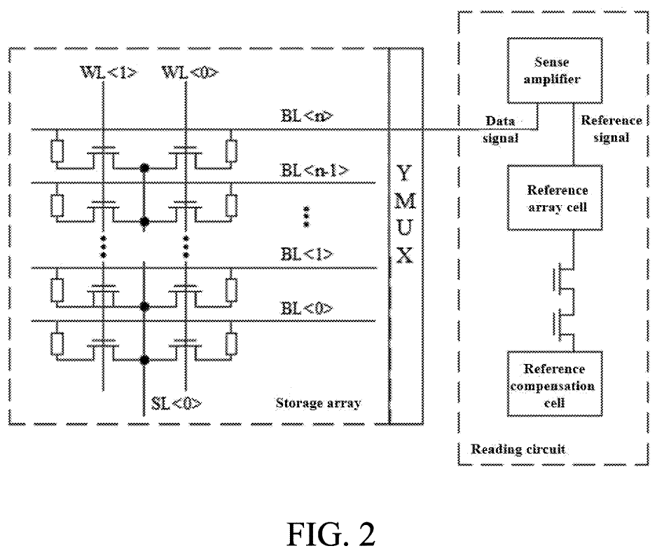

In an example, as shown in FIGS. 1 and 2, the reading circuit further includes a reference compensation cell, and an output terminal of the reference compensation cell is electrically connected to an input terminal of the reference array cell through a compensation switch transistor.

In an implementation mode, referring to FIG. 1, it can be seen that control signals of the second reference switch transistor are a reference switch signal Ref and a reference compensation signal SRT, respectively. In the above example, turning on the second reference switch is achieved through the reference switch signal Ref. Two compensation switch transistors on the reference compensation cell are the same as the reference switch, both MOS transistors, and the two control signals are a reference switch signal Ref and a reference compensation signal SRT, respectively, so they are the same as the control signal of the second reference switch transistor. In this example, the reference compensation signal SRT can be represented as SA REF TRIM<M:0>, which is a set of configurable digital control bits with a bit width of M+1 bits, numbered from 0 to M. By configuring different bit combinations, the electrical parameters of the reference array cell of the sense amplifier can be finely adjusted.

Therefore, in the reading circuit of RRAM, due to factors such as process deviation and device aging, the electrical characteristics of the reference path may differ from design values. By compensating for process deviation and parasitic effects through reference, the characteristics of the reference path and data path are fully symmetrical, ultimately improving the accuracy and reliability of memory read operations.

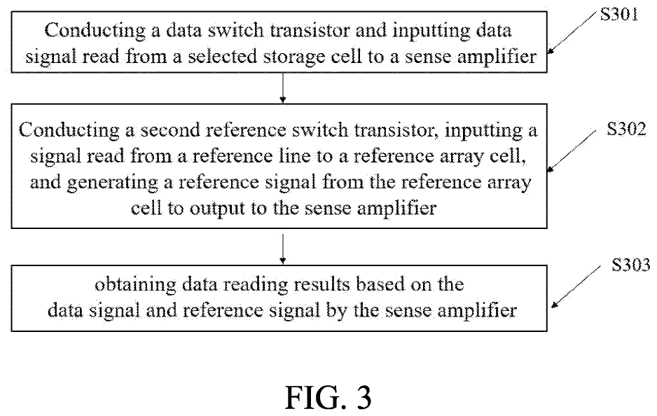

A second aspect of the present disclosure provides a control method applied to the memory of the first aspect, as shown in FIG. 3, the control method including the steps of:
S301: conducting a data switch transistor and inputting data signal read from a selected storage cell to a sense amplifier;
S302: conducting a second reference switch transistor, inputting a signal read from a reference line to a reference array cell, and generating a reference signal from the reference array cell to output to the sense amplifier;
S303: obtaining data reading results based on the data signal and reference signal by the sense amplifier.

As shown in FIG. 1, in this example, when reading the storage cells in a n^{th} row and a m^{th} column of the storage array, turning on a data switch on the storage array to input a data signal output by a Y multiplexer (YMUX) in the storage array to a data input terminal of the sense amplifier. At this point, selecting the reference line BLRef, turning on the second reference switch transistor on the reference array cell, so that read signal on the reference line of the reference cell is input to the input terminal of the reference array cell, and a reference signal generated by the reference array cell is output to a reference input terminal of the sense amplifier. At this point, the data path and reference path are completely symmetrical and also have unselected VDS leakage accumulation of the entire path, which is equivalent to the synchronous loss of the data signal and reference signal of the sense amplifier, thereby offsetting the parasitic and leakage effects.

In one example, as shown in FIGS. 1 and 2, the reading circuit further includes a reference compensation cell, and an output terminal of the reference compensation cell is electrically connected to an input terminal of the reference array cell through a compensation switch transistor.

In one example, step S402 further includes the following steps:
outputting a reference compensation signal, by the reference compensation cell, to the reference array cell by conducting the compensation switch transistor.

In an implementation mode, referring to FIG. 1, it can be seen that control signals of the second reference switch transistor are a reference switch signal Ref and a reference compensation signal SRT, respectively. In the above example, turning on the second reference switch is achieved through the reference switch signal Ref. Two compensation switch transistors on the reference compensation cell are the same as the reference switch, both MOS transistors, and the two control signals are a reference switch signal Ref and a reference compensation signal SRT, respectively, so they are the same as the control signal of the second reference switch transistor. In this example, the reference compensation signal SRT can be represented as SA REF TRIM<M:0>, which is a set of configurable digital control bits with a bit width of M+1 bits, numbered from 0 to M. By configuring different bit combinations, the electrical parameters of the reference array cell of the sense amplifier can be finely adjusted.

In a circuit simulation of the memory or the control method in the above example, the data in Table 1 is obtained.

TABLE 1
Comparison between the present disclosure and the prior art

| Unit: μA | I_{ref} | I_{cell} | I_{RRAM} | Difference |
|---|---|---|---|---|
| Prior art | −31.52 | −27.78 | −27.76 | 3.74 |
| The present | −27.59 | −27.78 | −27.76 | 0.19 |
| application | | | | |

According to Table 1, based on the simulation results of the existing technology, the current error between the reference signal I_{ref} and the data signal I_{cell} is as high as 3.74 μA, and there is a 13.5% error between the reference signal I_{ref} and the data signal I_{cell}. In this case, memory reading is prone to output errors due to current errors. When using the synchronous path of the present disclosure, the current error between the reference signal I_{ref} and the data signal I_{cell} is only 0.19 μA, and there is only 0.77% error between the reference signal I_{ref} and the data signal I_{cell}, which can be considered as I_{ref}≈I_{cell}. Therefore, the present disclosure achieves complete symmetry between the data path and the reference path to offset parasitic and leakage effects, thereby reducing errors at two ends of the sense amplifier data and improving the accuracy of reading.

In the description of the present disclosure, it should be understood that terms “first” and “second” are only used for descriptive purposes and cannot be understood as indicating or implying relative importance or implying the number of technical features indicated. Thus, the features limited to “first” and “second” may explicitly or implicitly include one or more of these features. In the description of the present disclosure, “a plurality of” means two or more, unless otherwise specifically limited.

In the present disclosure, unless otherwise specified and limited, the terms “installation”, “connection to”, “connection with”, “fixation”, etc. should be broadly understood, for example, it can be a fixed connection, a detachable connection, or integrated; it can be a mechanical connection or an electrical connection; it can be directly connected or indirectly connected through an intermediate medium; it can be a connection within two components or an interaction relationship between two components. For those skilled in the art, specific meanings of the above terms in the present disclosure can be understood according to the specific situation.

In the present disclosure, unless otherwise specified and limited, a first feature is located “above” or “below” a second feature, which may be direct contact between the first and second features, or indirect contact between the first and second features through an intermediate medium. Moreover, if the first feature is “above”, “on”, or “up” the second feature, it can be directly above or diagonally above the second feature, or simply indicate that the first feature is horizontally higher than the second feature. The first feature is “below”, “under”, and “beneath” the second feature, which can be directly or diagonally below the second feature, or simply indicate that the first feature is horizontally lower than the second feature.

In the description of this specification, terms “one embodiment”, “some embodiments”, “embodiments”, “examples”, “specific examples” or “some examples” refer to the specific features, structures, materials or characteristics described in combination with the embodiments or examples included in at least one embodiment or example of the present disclosure. In this specification, the schematic expressions of the above terms do not necessarily refer to the same embodiments or examples. Moreover, the specific features, structures, materials, or characteristics described can be combined in any one or more embodiments or examples in an appropriate manner. Furthermore, those skilled in the art can combine and incorporate different embodiments or examples described in this specification, as well as the features of different embodiments or examples, without conflicting with each other.

Although the embodiments of the present disclosure have been shown and described above, it can be understood that the above embodiments are exemplary and should not be construed as limiting the present disclosure. Those skilled in the art can modify, alter, substitute, and modify the above embodiments within the scope of the present disclosure.

What is claimed is:

1. A memory, wherein the memory comprises a reading circuit and a storage array, the storage array comprises a storage cell and at least one row of reference cells parallel to the storage cell, the reference cells comprise first reference switch transistors with the same number of storage switch transistors in the storage cell;
the reading circuit comprises a sense amplifier and a reference array cell; a data input terminal of the sense amplifier is electrically connected to a bit line of the storage cell through a data switch transistor, and a reference input terminal is electrically connected to an output terminal of the reference array cell; an input terminal of the reference array cell is electrically connected to a reference line that is connected to all reference cells through a second reference switch transistor.

2. The memory according to claim 1, wherein the storage array is an RRAM array.

3. The memory according to claim 2, wherein the reference cell comprises only two reference switch transistors that are connected.

4. The memory according to claim 1, wherein the reading circuit further comprises a reference compensation cell, and an output terminal of the reference compensation cell is electrically connected to the input terminal of the reference array cell through a compensation switch transistor.

5. The memory according to claim 4, wherein the compensation switch is the same as the second reference switch and has the same control signal.

6. A control method, wherein it is applied to the memory according to claim 1, the control method comprising the steps of:
conducting a data switch transistor and inputting data signal read from a selected storage cell to a sense amplifier;
conducting a second reference switch transistor, inputting a signal read from a reference line to a reference array cell, and generating a reference signal from the reference array cell to output to the sense amplifier;
obtaining data reading results based on the data signal and reference signal by the sense amplifier.

7. The control method according to claim 6, wherein the storage array is an RRAM array.

8. The control method according to claim 7, wherein the reference cell comprises only two first reference switch transistors that are connected.

9. The control method according to claim 6, further comprising the steps of:
outputting a reference compensation signal, by the reference compensation cell, to the reference array cell by conducting the compensation switch transistor.

10. The control method according to claim 9, wherein the compensation switch is the same as the second reference switch and has the same control signal.
